(19) United States
(12) Patent Application Publication
(10) Pub. No.: US 2009/0311863 A1
(43) Pub. Date: Dec. 17, 2009

(54) METHOD FOR PRODUCING SEMICONDUCTOR WAFER

(75) Inventors: Tomohiro Hashii, Tokyo (JP); Yuichi Kakizono, Tokyo (JP)

Correspondence Address: FITZPATRICK CELLA HARPER & SCINTO, 1290 Avenue of the Americas, NEW YORK, NY, 10104-3800, US

(73) Assignee: SUMCO CORPORATION, Tokyo (JP)

(21) Appl. No.: 12/475,876

(22) Filed: Jun. 1, 2009

(30) Foreign Application Priority Data
Jun. 16, 2008 (JP) 2008-157233

(51) Int. Cl. H01L 21/306; H01L 21/304; B24B 1/00

(52) U.S. Cl. 438/691; 451/57; 257/E21.219; 257/E21.237

(57) ABSTRACT

A semiconductor wafer is produced by a method comprising a slicing step of cutting out a thin disc-shaped semiconductor wafer from a crystalline ingot; a fixed grain bonded abrasive grinding step of sandwiching the semiconductor wafer between a pair of upper and lower plates each having a pad of fixed grain bonded abrasive to simultaneously grind both surfaces of the semiconductor wafer; and a one-side polishing step subjected to both surfaces of the semiconductor wafer after the fixed grain bonded abrasive grinding step.

### BACKGROUND OF THE INVENTION

1. Field of the Invention

This invention relates to a method for producing a semiconductor wafer, and more particularly to a method for producing a semiconductor wafer by cutting out a thin disc-shaped semiconductor wafer from a crystalline ingot and then subjecting both surfaces thereof to a mirror finishing.

2. Description of the Related Art

The conventional method for producing a semiconductor wafer typically comprises a series of a slicing step→a first beveling step→a lapping step→a second beveling step→a one-side grinding step→a double-sided polishing step→a one-side finish polishing step in this order.

In the slicing step, a thin disc-shaped semiconductor wafer is cut out from a crystalline ingot. In the first beveling step, an outer peripheral portion of the cut semiconductor wafer is beveled to suppress the occurrence of cracking or chipping in the semiconductor wafer at the subsequent lapping step. In the lapping step, the beveled semiconductor wafer is lapped with a grindstone of, for example, #1000 to increase a flatness of the semiconductor wafer. In the second beveling step, an outer peripheral portion of the lapped semiconductor wafer is beveled to render an end face of the semiconductor wafer into a given beveled form. In the one-side grinding step, a one-side face of the beveled semiconductor wafer is ground with a grindstone of, for example, #2000-8000 to approximate the thickness of the semiconductor wafer to a final thickness. In the double-sided polishing step, both surfaces of the one-side ground semiconductor wafer are polished. In the one-side finish polishing step, a one-side face of the double-sided polished semiconductor wafer as a device face is further subjected to finish polishing.

In the aforementioned conventional method, a double-sided mirror finished semiconductor wafer is produced through the two beveling steps, the lapping step and the one-side grinding step so that there are problems that a kerf loss of a semiconductor material (loss of semiconductor material due to the increase of lapped scrap and one-side ground scrap) is brought about due to a large number of steps.

Particularly, the above problem is remarkable on a large-diameter semiconductor wafer such as a silicon wafer having a diameter of not less than 450 mm. For example, when a silicon wafer having a diameter of not less than 450 mm is produced at the same machining allowance as a currently major silicon wafer having a diameter of 300 mm, the kerf loss of the silicon wafer is 2.25 times.

In addition, when the above-mentioned lapping step is added to the production method for a silicon wafer having a diameter of not less than 450 mm, the size of the lapping apparatus is considerably grown, which will be brought question on a place of disposing the lapping apparatus or the like in the formulation of the production line.

In Japanese Patent No. 3,328,193, a method for producing a semiconductor wafer, which comprises a double-sided grinding step instead of the lapping step in the above conventional method, is proposed.

In the production method of the semiconductor wafer disclosed in this patent document, the problem of growing the size of the lapping apparatus in the production of the large-diameter semiconductor wafer is solved and the first beveling step before the double-side grinding step are conducted, and hence the machining allowance of the silicon material is still large, which remains as a problem about the kerf loss.

Moreover, it is desired to improve the flatness of the semiconductor wafer, which will be anticipated to become more severe in future, by reducing the machining allowance of the semiconductor wafer.

### SUMMARY OF THE INVENTION

It is, therefore, an object of the invention to advantageously solve the above-mentioned problems and to provide a method for producing a semiconductor wafer wherein the beveling step for preventing the occurrence of cracking or chipping in the semiconductor wafer during the grinding is omitted, while working strain in the semiconductor wafer after the grinding is removed but also the beveling of the end face is conducted in case of mirror-finishing both surfaces of the semiconductor wafer cut out from a crystalline ingot, whereby the number of production steps is decreased and the machining allowance of silicon material in the semiconductor wafer is reduced to reduce the kerf loss of the semiconductor material to thereby obtain the semiconductor wafer cheaply. Particularly, the invention develops a remarkable effect when the semiconductor wafer is a silicon wafer having a diameter of not less than 450 mm.

In order to solve the above problems, the inventors have made various studies about a step capable of grinding the semiconductor wafer cut out from the crystalline ingot without beveling the end face thereof and an etching step of simultaneously conducting the removal of working strain in the semiconductor wafer after the grinding and the beveling of the end face thereof.

As a result, it has been found that the number of production steps can be decreased but also the machining allowance of the semiconductor wafer can be reduced as compared with the conventional method by conducting a fixed grain bonded abrasive grinding step of simultaneously conducting a treatment from rough grinding to finish grinding on both surfaces at once instead of the lapping step and the one-side grinding step in the above conventional method as well as a sheet-feed type etching step of simultaneously conducting not only removal of working strain on the surfaces and end face of the semiconductor wafer but also the beveling thereof.

The invention is based on the above knowledge and the summary and construction thereof are as follows.

1. A method for producing a semiconductor wafer, which comprises a slicing step of cutting out a thin disc-shaped semiconductor wafer from a crystalline ingot; a fixed grain bonded abrasive grinding step of sandwiching the semiconductor wafer between a pair of upper and lower plates each having a pad of fixed grain bonded abrasive to simultaneously grind both surfaces of the semiconductor wafer; and a one-side polishing step subjected to both surfaces of the semiconductor wafer after the fixed grain bonded abrasive grinding step.

2. A method for producing a semiconductor wafer, which comprises a slicing step of cutting out a thin-disc-shaped semiconductor wafer from a crystalline ingot; a fixed grain bonded abrasive grinding step wherein the semiconductor wafer is fitted into a circular hole of a carrier having a plurality of circular holes closely aligned to each other and thereafter the carrier is sandwiched between a pair of upper and lower plates each having a pad of a fixed grain bonded abrasive and then the upper and lower plates are rotated while oscillating the carrier in the same horizontal plane to simultaneously conduct a high-speed treatment from rough grinding to finish grinding on both surfaces of the semiconductor wafer at once; a chemical treating step of simultaneously conducting reduction of working strain on the surfaces and an end face of the semiconductor wafer after the fixed grain bonded abrasive grinding step and a finish beveling of rendering the end face of the semiconductor wafer into a given beveled form; and a one-side finish polishing of finish polishing the surface of the semiconductor wafer after the chemical treating step.

3. A method for producing a semiconductor wafer according to the item 1 or 2, wherein the semiconductor wafer is a silicon wafer having a diameter of not less than 450 mm.

According to the production method of the semiconductor wafer according to the invention, the fixed grain bonded abrasive grinding step is conducted after the slicing step, and further the sheet-feed type etching step subjected to each of both surfaces of the semiconductor wafer after the fixed grain bonded abrasive grinding step and the one-face finish polishing step subjected to the surface of the semiconductor wafer added with the etching solution at the sheet-feed type etching step are conducted, whereby the number of production steps for the semiconductor wafer is shortened as compared with the conventional method and the machining allowance of the semiconductor wafer can be reduced to reduce the kerf loss of the semiconductor material to thereby obtain the semiconductor wafer cheaply.

Also, the flatness of the semiconductor wafer can be improved by reducing the machining allowance of the semiconductor wafer. Furthermore, a semiconductor wafer having an epitaxial layer can be obtained by conducting an epitaxial layer growing step after the chemical treating step or the one-side finish polishing step. The production method of the semiconductor wafer according to the invention is especially suitable for the production of silicon wafers having a diameter of not less than 450 mm.

### BRIEF DESCRIPTION OF THE DRAWINGS

The invention will be described with reference to the accompanying drawings, wherein:

FIG. 1 is a flow chart showing production steps according to an embodiment of the invention;

FIG. 2 (a) is a schematic cross-sectional view of an apparatus used in a fixed grain bonded abrasive grinding step;

FIG. 2 (b) is a schematic top view of the apparatus showing a state just before the start of the fixed grain bonded abrasive grinding step;

FIG. 2 (c) is a schematic top view of the apparatus showing a state after a predetermined time of the fixed grain bonded abrasive grinding step;

FIG. 3 is a schematic cross-sectional view and a top view of an apparatus used in the conventional lapping step;

FIG. 4 is a flow chart showing production steps of Conventional Example 1; and

FIG. 5 is a flow chart showing production steps of Conventional Example 2.

### DESCRIPTION OF THE PREFERRED EMBODIMENTS

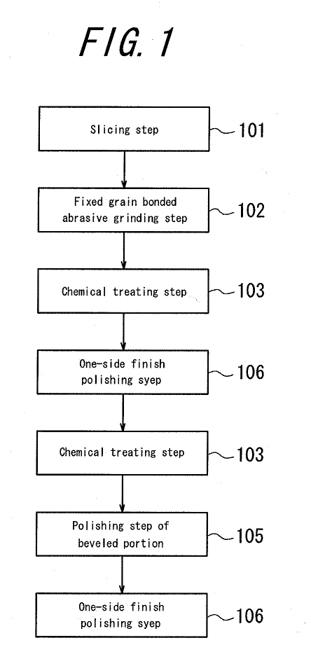

FIG. 1 is a flow chart showing production steps according to an embodiment of the invention. In this embodiment of the invention, the following three steps (1) to (3) are conducted in this order:

(1) a slicing step of cutting out a thin disc-shaped semiconductor wafer from a crystalline ingot;

(2) a fixed grain bonded abrasive grinding step wherein the semiconductor wafer is fitted into a circular hole of a carrier having a plurality of circular holes closely aligned to each other and thereafter the carrier is sandwiched between a pair of upper and lower plates each having a pad of a fixed grain bonded abrasive and then the upper and lower plates are rotated while oscillating the carrier in the same horizontal plane to simultaneously conduct a high-speed treatment from rough grinding to finish grinding on both surfaces of the semiconductor wafer at once; and

(3) a chemical treating step of simultaneously conducting reduction of working strain on the surfaces and an end face of the semiconductor wafer after the fixed grain bonded abrasive grinding step and a finish beveling of rendering the end face of the semiconductor wafer into a given beveled form, and a one-side finish polishing step of finish polishing the surface of the semiconductor wafer added with the etching solution at the chemical treating step.

Next, the each step in the embodiment of the invention will be described.

(Slicing Step)

The slicing step is a step of cutting out a thin disc-shaped wafer by contacting a wire saw with a crystalline ingot while supplying a grinding solution, or by cutting a crystalline ingot with an inner diameter blade. In order to reduce a processing load in the subsequent fixed grain bonded abrasive grinding step or sheet-feed type etching step, the semiconductor wafer after the slicing step is preferable to have a high flatness and a small surface roughness as far as possible.

Moreover, the crystalline ingot is typically an ingot of silicon single crystal, but may be an ingot of polycrystalline silicon for solar cells.

(Fixed Grain Bonded Abrasive Grinding Step)

The fixed grain bonded abrasive grinding step is a step of roughly grinding both surfaces of the semiconductor wafer cut in the slicing step to increase the flatness and to approximate the thickness of the semiconductor wafer to the final thickness.

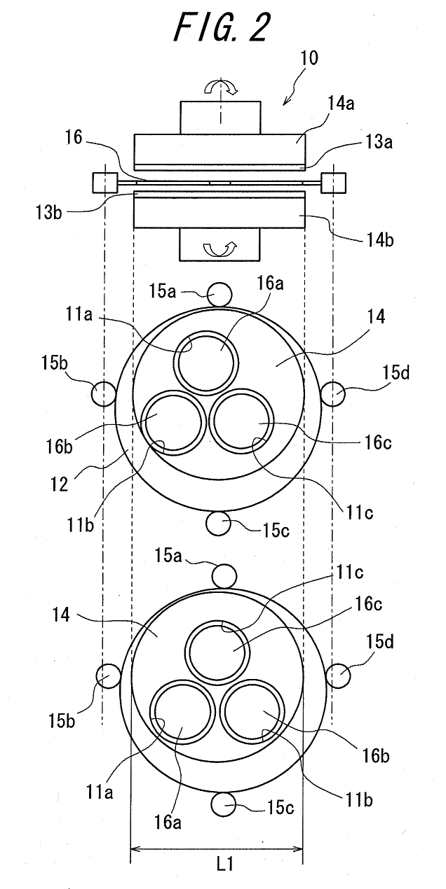

FIG. 2 is a schematic view of a fixed grain bonded abrasive grinding apparatus 10 used in the fixed grain bonded abrasive grinding step, wherein FIG. 2 (a) is a cross-sectional view of the apparatus 10 used in the fixed grain bonded abrasive grinding step and FIGS. 2 (b) and (c) are top views of the apparatus 10 used in the fixed grain bonded abrasive grinding step, respectively. FIGS. 2 (a) and (b) show states just before the start of the fixed grain bonded abrasive grinding step, and FIG. 2 (c) view shows a state after a predetermined time of the fixed grain bonded abrasive grinding step.

The fixed grain bonded abrasive grinding apparatus 10 comprises a carrier 12 having a plurality of circular holes 11a, 11b and 11c closely aligned to each other, pads 13a, 13b each having a fixed grain bonded abrasive, a pair of upper and lower plates 14a, 14b having the pads 13a and 13b, and guide rollers 15a, 15b, 15c, 15d arranged so as to contact with a side face of the carrier 12 at four divided positions of the circumference of the carrier 12.

The semiconductor wafers 16a, 16b, 16c cut out in the slicing step are fitted into the circular holes 11a, 11b, 11c of the carrier 12, and thereafter the carrier 12 is sandwiched between the pair of upper and lower plates 14a, 14b having the pads 13a, 13b with the fixed grain bonded abrasive, and then the upper and lower plates 14a, 14b are rotated while moving the guide rollers 15a, 15b, 15c, 15d to oscillate the carrier 12 in the same horizontal plane, whereby both surfaces of each of the wafers 16a, 16b, 16c are ground simultaneously.

Although there are shown three circular holes 11a, 11b, 11c in the FIG. 2, the number of circular holes is not limited to three. However, as shown in FIGS. 2 (b) and (c), it is important that all of the circular holes 11a, 11b, 11c are disposed so as to enter into the circumferences of the upper and lower plates 14a, 14b even if the carrier 12 takes any positional relationship with respect to the upper and lower plates 14a, 14b through oscillating. This is due to the fact that a pressure applied to the semiconductor wafer during the fixed gain bonded abrasive grinding is made uniform as far as possible, whereby the occurrence of cracking or chipping in the semiconductor wafer during the fixed grain bonded abrasive grinding is prevented but also the flatness of the semiconductor wafer after the fixed grain bonded abrasive grinding is improved without beveling an outer peripheral portion of the semiconductor wafer after the slicing step. It is preferable that the circular hole 11 has the same diameter and the number thereof is 3, because as shown in FIGS. 2 (b) and (c), if the circular holes 11a, 11b, 11c are aligned closely to each other, the diameter of the plates 14 can be made minimum and the size of the fixed grain bonded abrasive grinding apparatus 10 is not unnecessarily grown. When the diameter of the plate 14 is L1 in FIG. 2, L1 if three silicon wafers each having a diameter of 450 mm are ground with the fixed grain bonded abrasive is approximately 985 mm.

Since the pad has the fixed grain bonded abrasive, it is not required to supply a slurry of free abrasive grains during the fixed grain bonded abrasive grinding. Therefore, it is possible to avoid the deterioration of the flatness of the semiconductor wafer after the grinding due to non-uniform supply of the free abrasive grains, which is especially advantageous in a case that a diameter of the semiconductor wafer is large as in a silicon wafers having a diameter of not less than 450 mm and it is difficult to supply the free abrasive grains uniformly.

The material of the abrasive grains in the pad having the fixed grain bonded abrasive is generally diamond, but abrasive grains of SiC may be also used. Although the pad with the fixed grain bonded abrasive may have a roughness of #1000˜8000, as previously mentioned, the pressure applied to the semiconductor wafer during the fixed grain bonded abrasive grinding is uniform and the grinding action of the abrasive grains to the semiconductor wafer is uniform owing to the use of the fixed grain bonded abrasive instead of the free abrasive grains, so that it is possible to conduct a high-speed treatment from rough grinding to finish grinding at once without occurrence of cracking or chipping even if a semiconductor wafer having a rough surface state just after the slicing step is subjected to a fixed grain bonded abrasive grinding with a fine pad of about #8000.

During the fixed grain bonded abrasive grinding, it is preferable to wash out ground scraps, or to supply water or an alkali solution for the purpose of lubrication.

Moreover, when a grinding margin at the fixed grain bonded abrasive grinding step is less than 20 μm per one-side surface, the undulation of the wafer generated in the cutting will be a problem, while when it exceeds 50 μm, the strength of the wafer becomes lacking. Therefore, the grinding margin at the fixed grain bonded abrasive grinding step is preferable to be 20-50 μm per one-side surface.

Now, the lapping step will be briefly described to compare the fixed grain bonded abrasive grinding step employed in the invention with the lapping step employed in the conventional method.

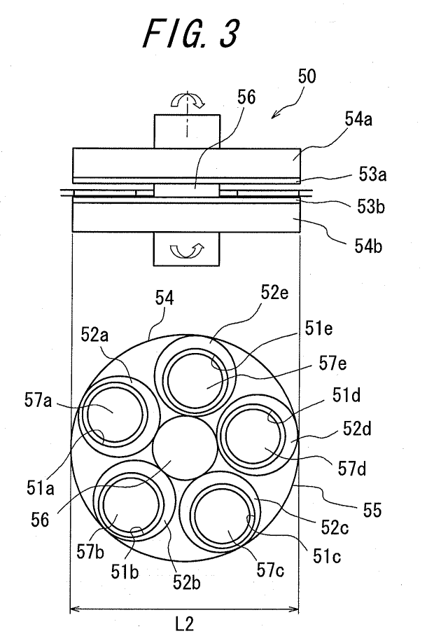

In the FIG. 3 is schematically shown an apparatus used in the lapping step employed in the conventional method. The lapping apparatus 50 comprises carriers 52a, 52b, 52c, 52d, 52e each having a respective circular hole 51a, 51b, 51c, 51d, or 51e and provided on its side face with a gear, pads 53a, 53b, a pair of upper and lower plates 54a, 54b having the pads 53a, 53b, an outer peripheral guide 55 in the sun-and-planet motion of the carriers 52a, 52b, 52c, 52d, 52e, and a center gear 56 engaging with the gears provided on the side faces of the carriers 52a, 52b, 52c, 52d, 52e.

The semiconductor wafers 57a, 57b, 57c, 57d, 57e cut in the slicing step are fitted into the circular holes 51a, 51b, 51c, 51d, 51e of the carriers 52a, 52b, 52c, 52d, 52e, and thereafter the carriers 52a, 52b, 52c, 52d, 52e are sandwiched between the pair of the upper and lower plates 54a, 54b having the pads 53a, 53b, and then the center gear 56 is rotated to conduct the sun-and-planet motion of the carriers 52a, 52b, 52c, 52d, 52e along the guide 55 while supplying free abrasive grains to the wafers 57a, 57b, 57c, 57d, 57e, to thereby lap the wafers 57a, 57b, 57c, 57d, 57e.

In the lapping apparatus 50, the area occupied by the center gear 56 is large and the area of the plate 54 becomes large accompanied therewith, and hence the whole size of the lapping apparatus 50 tends to be grown. In the lapping of the large-diameter semiconductor wafers, the sizes of the carriers 52a, 52b, 52c, 52d, 52e are grown and hence the force required for the sun-and-planet motion of the carriers 52a, 52b, 52c, 52d, 52e becomes large to grow the size of the center gear 56, and as a result, the size of the lapping apparatus 50 becomes more larger, which is a serious problem. In FIG. 3, when the diameter of the plate 54 is L2, if three semiconductor wafers of 450 mm in diameter are lapped, L2 is about 2200 mm, which is much larger than L1 in the fixed grain bonded abrasive grinding apparatus 10. Thus, when silicon wafers having a diameter of not less than 450 mm are produced by a method including the lapping step, it is required to use a very large lapping apparatus, which may cause a problem in the installation site and the like.

Also, in the lapping step, the size of the guide becomes larger since the lapping is conducted while supplying free abrasive grains. As a result, the supply area of free abrasive grains becomes wider, and it is difficult to supply them uniformly, which may easily deteriorate the flatness of the semiconductor wafer after the lapping step but also may cause the cracking or chipping in the lapping.

(Chemical Treating Step)

The chemical treating step simultaneously conducts reduction of working strain on the surfaces and end face of the semiconductor wafer applied at the slicing step or both the slicing step and the fixed grain bonded abrasive grinding step, and a finish beveling of making the end face of the semiconductor wafer to a given beveled form, which may be either a batch type or a sheet-feed type chemical treatment.

The batch type chemical treatment is a treatment of immersing a plurality of semiconductor wafers (e.g. 24 wafers) into a vessel containing a given etching solution to simultaneously conduct the reduction of working strain on both surfaces and end faces of the semiconductor wafer and the finish beveling of making the end face of the semiconductor wafer to a given beveled form. Therefore, it is possible to shorten the number of production steps as a whole in the production method of the semiconductor wafer without separately conducting a step of beveling the end face of the semiconductor wafer.

The sheet-feed type chemical treating step is a treatment that one semiconductor wafer is rotated while adding dropwise an etching solution to a one-side face of the semiconductor wafer, whereby the etching solution is extended over the both surfaces and end faces of the semiconductor wafer through centrifugal force to reduce working strain on both the surfaces and end face of the semiconductor wafer, and at the same time the end face of the semiconductor wafer is subjected to a finish beveling to a given beveled form. The sheet-feed type chemical treatment is subjected twice to each one-side face before and after the following one-side finish polishing so that both surfaces of the semiconductor wafer are etched. On the end face, conditions of etching are set for making a given form by two etching.

As the etching solution, it is preferable to use a mixed acids of hydrofluoric acid, nitric acid and phosphoric acid, because it is required that when the etching solution is added dropwise to the rotating semiconductor wafer, it is extended over the surface of the semiconductor wafer to be etched at a proper rate to form a uniform film of the etching solution on this surface. A mixed acid of hydrofluoric acid, nitric acid and acetic acid usually used as the etching solution in the immersion etching is not preferable because it is low in the viscosity and when it is added dropwise to the rotating semiconductor wafer, a rate of extending over the surface to be etched is too fast and the film of the etching solution is not formed, resulting in irregular etching.

Moreover, the mixed acid of hydrofluoric acid, nitric acid and phosphoric acid used as the etching solution in the sheet-feed type chemical treatment is preferable to comprise 5˜20 mass % of hydrofluoric acid, 5˜40 mass % of nitric acid, 30˜40 mass % of phosphoric acid.

(One-Side Finish Polishing Step)

In the one-side finish polishing step, a surface of the sheet-feed type etched semiconductor wafer is polished with a polishing cloth made of urethane or the like while supplying a polishing slurry. The kind of the polishing slurry is not particularly limited, but colloidal silica having a particle size of not more than 0.5 μm is preferable.

The one-side finish polishing step is conducted twice before and after the sheet-feed type etching, and a surface of the second one-side finish polished semiconductor wafer finally becomes a device surface.

Although the above is described with respect to the main steps in the production method according to the invention, a polishing step of beveled portion and/or an epitaxial layer growing step may be included, if desired. The polishing step of beveled portion and the epitaxial layer growing step will be described below.

(Polishing Step of Beveled Portion)

The polishing step of the beveled portion is conducted after the second sheet-feed type etching step for polishing the beveled portion of the semiconductor wafer to reduce a variation of the beveled width in the wafer. In this case, the beveled portion is polished with an abrasive cloth made of urethane or the like while supplying an abrasive slurry. The kind of the abrasive slurry is not particularly limited, but colloidal silica having a particle size of about 0.5 μm is preferable.

(Epitaxial Layer Growing Step)

A semiconductor wafer having an epitaxial layer can be obtained by conducting the epitaxial layer growing step after the chemical treating step or the one-side finish polishing step. When the epitaxial layer is grown on the surface of the semiconductor wafer, it is required to remove surface damage of the semiconductor wafer applied at the slicing step and optionally at the fixed grain bonded abrasive grinding step, so that the epitaxial layer growing step is preferable to be conducted after the chemical treating step or the one-side finish polishing step.

Although the above is merely described with respect to one embodiment of the invention, various modifications may be made without departing from the scope of the appended claims.

A semiconductor wafer is prepared by the production method according to the invention as stated below.

### Invention Example 1

A silicon wafer having a diameter of 300 mm is prepared according a flow chart shown in FIG. 1 according to the embodiment of the invention.

### Invention Example 2

A silicon wafer having a diameter of 450 mm is prepared in the same production method as in Invention Example 1.

### Conventional Example 1

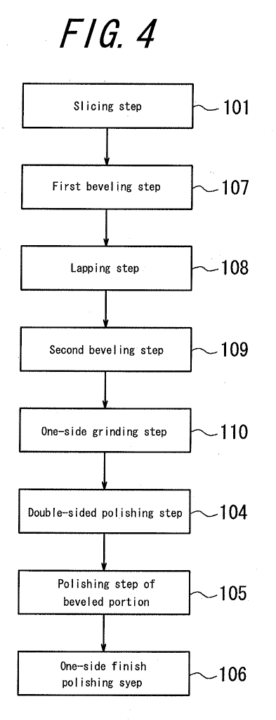

A silicon wafer having a diameter of 300 mm is prepared by the conventional production method shown in FIG. 4 inclusive of a lapping step.

### Conventional Example 2

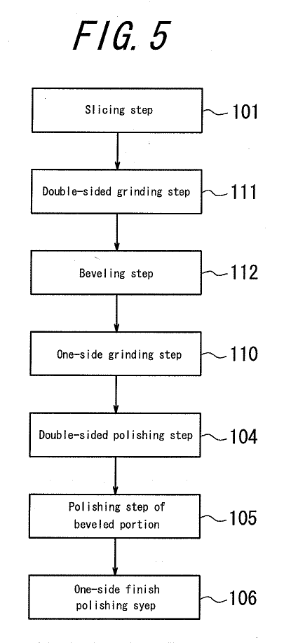

A silicon wafer having a diameter of 300 mm is prepared by a production method shown in FIG. 5 using a double-sided polishing step instead of the lapping step.

With respect to each of the thus obtained samples are evaluated the silicon kerf loss and flatness. The evaluation method will be described below.

(Silicon Kerf Loss)

The silicon kerf loss is evaluated by a reduction quantity (μm) of a thickness in the semiconductor wafer before and after the fixed grain bonded abrasive grinding step in Invention Examples 1 and 2, the sum of a reduction quantity (μm) of a thickness in the semiconductor wafer before and after the lapping step and a reduction quantity (μm) of a thickness in the semiconductor wafer before and after the one-side grinding step in Conventional Example 1, and the sum of a reduction quantity (μm) of a thickness in the semiconductor wafer before and after the double-sided grinding step and a reduction quantity (μm) of a thickness in the semiconductor wafer before and after the one-side grinding step in Conventional Example 2.

(Flatness)

The flatness of each sample is measured with a capacitance type thickness sensing meter and is evaluated as follows:

◯: The flatness is less than 0.5 Mm.
Δ: The flatness is not less than 0.5 μm but not more than 1 μm.
X: The flatness is more than 1 μm.

The evaluation results of the each sample are shown in Table 1.

TABLE 1

| | Invention | Invention | Conventional | Conventional |
|---|---|---|---|---|
| | Example 1 | Example 2 | Example 1 | Example 2 |
| Flow chart | FIG. 1 | FIG. 1 | FIG. 4 | FIG. 5 |
| Diameter (mm) | 300 | 450 | 300 | 300 |
| Silicon kerf loss | 45 | 65 | 100 | 105 |
| (ground thickness: | | | | |
| (μm)) | | | | |
| Flatness | ◯ | ◯ | Δ | Δ |

As seen from Table 1, Invention Example 1 shows a minimum value of the silicon kerf loss and a good flatness. Invention Example 2 shows good results substantially equal to those in Invention Example 1, from which it has been confirmed that a silicon wafer having a diameter of 450 mm is obtained by the production method according to the first embodiment of the invention. On the other hand, Conventional Examples 1 and 2 show a large silicon kerf loss and a poor flatness as compared with Invention Examples 1 and 2.

According to the production method of the semiconductor wafer according to the invention, the fixed grain bonded abrasive grinding step is conducted after the slicing step, and further the sheet-feed type etching step subjected to each of both surfaces of the semiconductor wafer after the fixed grain bonded abrasive grinding step and the one-face finish polishing step subjected to the surface of the semiconductor wafer added with the etching solution at the sheet-feed type etching step are conducted, whereby the number of production steps for the semiconductor wafer is shortened as compared with the conventional method and the machining allowance of the semiconductor wafer can be reduced to reduce the kerf loss of the semiconductor material to thereby obtain the semiconductor wafer cheaply. Also, the flatness of the semiconductor wafer can be improved by reducing the machining allowance of the semiconductor wafer. Furthermore, a semiconductor wafer having an epitaxial layer can be obtained by conducting an epitaxial layer growing step after the chemical treating step and the one-side polishing step. The production method of the semiconductor wafer according to the invention is especially suitable for the production of silicon wafers having a diameter of not less than 450 mm.

What is claimed is:

1. A method for producing a semiconductor wafer, which comprises a slicing step of cutting out a thin disc-shaped semiconductor wafer from a crystalline ingot; a fixed grain bonded abrasive grinding step of sandwiching the semiconductor wafer between a pair of upper and lower plates each having a pad of fixed grain bonded abrasive to simultaneously grind both surfaces of the semiconductor wafer; and a one-side polishing step subjected to both surfaces of the semiconductor wafer after the fixed grain bonded abrasive grinding step.

2. A method for producing a semiconductor wafer, which comprises a slicing step of cutting out a thin-disc-shaped semiconductor wafer from a crystalline ingot; a fixed grain bonded abrasive grinding step wherein the semiconductor wafer is fitted into a circular hole of a carrier having a plurality of circular holes closely aligned to each other and thereafter the carrier is sandwiched between a pair of upper and lower plates each having a pad of a fixed grain bonded abrasive and then the upper and lower plates are rotated while oscillating the carrier in the same horizontal plane to simultaneously conduct a high-speed treatment from rough grinding to finish grinding on both surfaces of the semiconductor wafer at once; a chemical treating step of simultaneously conducting reduction of working strain on the surfaces and an end face of the semiconductor wafer after the fixed grain bonded abrasive grinding step and a finish beveling of rendering the end face of the semiconductor wafer into a given beveled form; and a one-side finish polishing of finish polishing the surface of the semiconductor wafer after the chemical treating step.

3. A method for producing a semiconductor wafer according to claim 1 or 2, wherein the semiconductor wafer is a silicon wafer having a diameter of not less than 450 mm.
